(19) United States
(12) Patent Application Publication
(10) Pub. No.: US 2007/0020908 A1
(43) Pub. Date: Jan. 25, 2007

(54) Multilayer structure having a warpage-compensating layer

(75) Inventors: Kenneth Allen Honer, Santa Clara, CA (US); Sridhar Krishnan, San Francisco, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/183,421

(22) Filed: Jul. 18, 2005

(51) Int. Cl. H01L 21/44

(52) U.S. Cl. 438/612

(57) ABSTRACT

A multilayer structure is provided that includes a semiconductor member having opposing first and second major surfaces, a warpage-compensating layer deposited on the first major surface, and a substrate bonded to the second major surface. The warpage-compensating layer has a stiffness and a coefficient of thermal expansion keyed to the substrate in a manner effective to reduce warpage of the semiconductor member. Also provided is a method for forming a multilayer structure.

### FIELD OF THE INVENTION

The present invention relates generally to a multilayer structure that includes a semiconductor member having a substrate bonded thereto. In particular, the invention relates to such a structure having a layer deposited on the semiconductor member to compensate for package and/or member warpage that may be associated with member-substrate bonding. Also provided are methods for forming multilayer structures.

### BACKGROUND OF THE INVENTION

Microelectronic devices such as semiconductor chips are often packaged with a substrate to provide a convenient vehicle for mounting and establishing electrical connections to the device. For example, semiconductor chips typically are flat bodies with contacts that are disposed on the front surface and connected to the internal electrical circuitry of the chip itself. Semiconductor chips may be bonded to substrates to form microelectronic packages having terminals electrically connected to the chip contacts.

While any of a number of materials may be used to form the substrate, substrate materials are selected for their compatibility with the processes used to form the package as well as the requirements associated with the use of the package itself. For example, during certain bonding operations, such as those involving solder flow, intense heat may be applied to the substrate. Accordingly, polymeric substrates used to package microelectronic devices may include successive fiberglass layers may be laid in traversing, e.g., orthogonal, directions, and/or heat resistive compounds such as bismaleimide triazine (BT) to maintain the substrate's structural integrity.

In addition, polymeric tapes in the form of sheets or rolls of sheets may be used as the substrate. For example, single and double sided sheets of copper-on-polyimide are commonly used for fine-line and high-density electronic interconnection applications. Polyimide base films offer good thermal and chemical stability and a low dielectric constant, while copper having high tensile strength, ductility, and low electrical resistivity have been advantageously used in both flexible circuit and chip scale packaging applications.

As electronic products are becoming increasingly miniaturized, there is a need to reduce the size of microelectronic packages as well. In some instances, package size reduction may be achieved by reducing the dimensions of the semiconductor chip and/or the substrate packaged therewith. For example, there has been an effort to package semiconductor chips having a thickness of as about 75 μm or less. However, such chips exhibit are typically less stiff and will undergo greater warping when compared with their thicker counterparts when subjected to same forces. In addition, warpage of the substrate itself has been identified as a problem in microelectronic packaging in U.S. Pat. No. 6,835,897 to Chang et al.

When a thin semiconductor member such as a die is bonded to a substrate of a different composition, the member may experience warpage problems associated with thermal expansion mismatch. For example, polymeric materials typically have a coefficient of thermal expansion (CTE) that is at least about five to ten times higher than that for semiconductor materials. Accordingly, when a polymeric substrate is bonded to a major surface of a semiconductor die to form a semiconductor package, the polymeric substrate will tend to expand and contract to a greater extent than the die in response to a temperature change. In turn, the die may flex or warp as a result of the forces associated with the different rates of thermal expansion.

As discussed above, warpage may be particularly pronounced for thin dies since thin dies tend to strain more easily under the same force than their thicker counterparts. Similarly, packages having thick substrates also tend to have die warpage problems since such thick substrates provide a greater deformation force than thin substrates under similar thermal conditions. Furthermore, while warpage may be reduced by bonding an additional polymeric substrate to an opposing surface of the die such that the forces provided by the substrates balance one another, the additional substrate will tend to increase the thickness of the package to an undesirable or unacceptable extent.

Accordingly, there is a need in the art to reduce warpage of a semiconductor member, e.g., a thin semiconductor die, bonded to a substrate of a different CTE, particularly in a manner that is consistent with the goals of miniaturization.

### SUMMARY OF THE INVENTION

In a first aspect, the invention provides a multilayer structure that includes a semiconductor member having opposing first and second major surfaces, a warpage-compensating layer deposited on the first major surface, and a substrate bonded to the second major surface. The warpage-compensating layer has a stiffness and a coefficient of thermal expansion keyed to the substrate in a manner effective to reduce warpage of the semiconductor member by at least 10%, optionally by at least 20% to 50% or more. Warpage reduction may take place over a selected temperature range that spans, for example, over 60° C. to 100° C. or more. For example, warpage reduction may be particularly desirable from a temperature range of −40° C. to about 25° C. Typically, the semiconductor member includes a microelectronic device in the form of a semiconductor chip.

The warpage-compensating layer may have a composition different from the member, and the substrate may have a composition different from the warpage-compensating layer. Furthermore, the semiconductor member may have a composition different from the substrate as well. For example, the warpage-compensating layer may comprise a metal, and the substrate may comprise a polymer. Optionally, the substrate and the warpage-compensating layer may have coefficients of thermal expansion that differ by at least 5 pm/° C. or 10 ppm/° C.

The invention is particularly useful when the semiconductor member is thin and prone to warpage, e.g., has a thickness of no more than about 75 μm to 150 μm. The invention is also particularly suited for use when the member and substrate have coefficients of thermal expansion that differ by a significant degree, e.g., by at least 10 ppm/° C. or 20 ppm/° C. To reduce the profile of the structure, the warpage-compensating layer may have a modulus of elasticity that is high relative to that of the substrate, e.g., at least 50 GPa or 100 GPa higher than that of the substrate.

In another aspect, a method is provided for forming a multilayer structure. The method involves depositing a warpage-compensating layer on a major surface of a semiconductor member. The warpage-compensating layer may be deposited while the semiconductor member is an integral section of a semiconductor wafer, which may be later sectionalized. The method also involves bonding a substrate to the semiconductor member at a second major surface opposing the first major surface. Such bonding may take place at an elevated temperature, e.g., at least 100° C. As a result, of proper materials selection and processing, warpage of the semiconductor member is reduced by at least 10% over a selected temperature range.

### BRIEF DESCRIPTION OF THE DRAWINGS

FIGS. 1A-1C, collectively referred to as FIG. 1, schematically depict in cross-sectional view a microelectronic package formed from a microelectronic device and substrate using a method that renders the package prone to warpage. FIG. 1A depicts the package before assembly. FIG. 1B shows the application of heat to melt solder balls between the substrate and the device to form solder bonds therebetween. FIG. 1C depicts the warping of the package as a result of cooling.

FIGS. 2A-2C, collectively referred to as FIG. 2, schematically depict in cross-sectional view a microelectronic package formed from a microelectronic device having a warpage-compensating layer on a surface thereof and substrate using a method similar to that depicted in FIG. 1.

FIG. 3 is a graph that plots the results of experimental data that illustrates the extent to which semiconductor die warpage may be reduced in a microelectronic package that includes a warpage-compensating layer.

FIGS. 4A and 4B, collectively referred to as FIG. 4, set forth data and results, respectively, from a computer simulation that illustrates the extent to which semiconductor die warpage may be reduced in a microelectronic package that includes a warpage-compensating layer.

### DETAILED DESCRIPTION

Before describing the present invention in detail, it is to be understood that the invention is not limited to specific microelectronic devices or types of electronic products, as such may vary. It is also to be understood that the terminology used herein is for the purpose of describing particular embodiments only, and is not intended to be limiting.

As used in this specification and the appended claims, the singular article forms “a,” “an,” and “the” include both singular and plural referents unless the context clearly dictates otherwise. Thus, for example, reference to “a semiconductor member” includes a plurality of members as well as a single member; reference to “a surface” includes one or more surfaces, and the like.

In addition, terminology indicative or suggestive of a particular spatial relationship between elements of the invention is to be construed in a relative sense rather an absolute sense unless the context of usage clearly dictates to the contrary. For example, the term “over” as used to describe the spatial orientation of a semiconductor member relative to a substrate does not necessarily indicate that the member is located above the substrate. Thus, in a layered structure that includes a semiconductor member placed over a substrate, the member may be located above, at the same level as, or below the substrate depending on the structure's orientation. Similarly, an “upper” surface of a substrate may lie above, at the same level as, or below other portions of the substrate depending on the orientation of the substrate.

In general, the invention pertains to a multilayer structure that includes a semiconductor member having opposing first and second major surfaces and a substrate bonded to the substrate in a manner that may render the structure prone to warping. To reduce or eliminate warpage of the structure in part or in whole, a warpage-compensating layer may be used. For example, when a semiconductor member is bonded to a substrate of a non-semiconductor material to form a microelectronic package, the package may be prone to warpage. Consequently, a warpage-compensating layer may be deposited on the semiconductor member to reduce or eliminate warpage. Such a warpage-compensating layer typically has a stiffness and a coefficient of thermal expansion keyed to that of the substrate in a manner effective to reduce warpage of the semiconductor member or another component of the package by a substantial degree, e.g., by at least 10%. In addition, the semiconductor member may be interposed between the warpage-compensating layer and the substrate such that the opposing major surfaces of the semiconductor member face the warpage-compensating layer and the substrate.

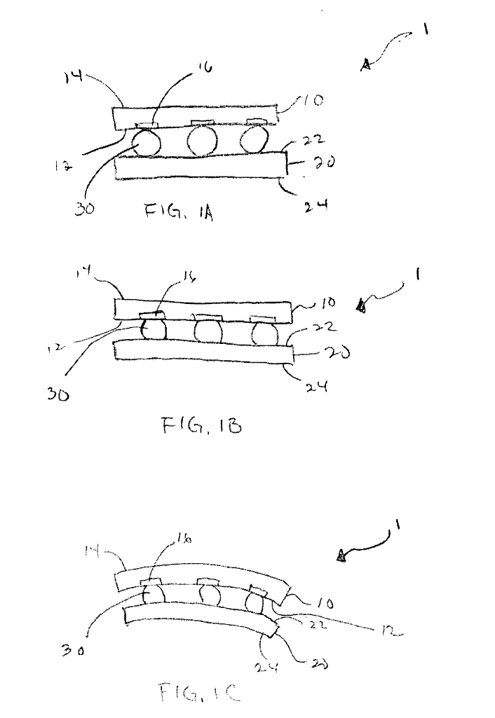

The invention may be used to supplement known technologies pertaining to multilayer structures such as microelectronic packages. To illustrate the advantages of the invention, FIG. 1 depicts a microelectronic package formed using a method that renders the package prone to warpage. As with all figures referenced herein, in which like parts are referenced by like numerals, FIG. 1 is not necessarily to scale, and certain dimensions may be exaggerated for clarity of presentation. As shown in FIG. 1, the package 1 includes microelectronic device 10 in the form of a semiconductor chip having first and second opposing major surfaces indicated at 12 and 14, respectively. The front surface 12 and rear surface 14 are depicted as substantially planar, rectangular in shape, and parallel to each other. The front surface 12 of the microelectronic device 10 includes a plurality of electrical contacts 16 that provides electrical accessibility to circuitry within the microelectronic device 10.

A substrate 20 is also shown in FIG. 1. The substrate 20 exhibits a higher CTE than the microelectronic device and has first and second surfaces, indicated at 22 and 24, respectively. As shown in FIG. 1, the package may be formed by placing the front surface 12 of the device 10 in facing relationship to the first surface 22 of the substrate 20. In some instances, the device may be bonded directly to the substrate. Alternatively, the device may be bonded indirectly, e.g., through an intermediary, to the substrate. In any case, as depicted in FIG. 1A, a plurality of solder balls 30 may be placed between the device 10 and the substrate 20. Then, as shown in FIG. 1B, the package may be heated such that the solder balls 30 are at least partially melted so as to facilitate the flow of solder to conform to the first surface 22 of the substrate 20 and the front surface 12 of the device 10 at electrical contacts 16. As a result, the device 10 electrically communicates with the substrate 20 via solder balls 30 in a flip-chip configuration.

Then, as shown in FIG. 1C, the package may be cooled so that solder balls 30 solidify and form solder bonds between the device 10 and the substrate 20. As a result, the device 10 is indirectly and generally rigidly bonded through the solder balls 30 to the substrate 20. Upon cooling, however, it becomes evident that the package is a thermal bimorph as the substrate 20 contracts to a greater degree than the device 10 as a result of the substrate's higher CTE. As a result, the device 10 and the package may become warped as the front and rear device surfaces 12, 14 may exhibit concave and convex profiles, respectively. Similarly, the substrate 20 becomes warped as well.

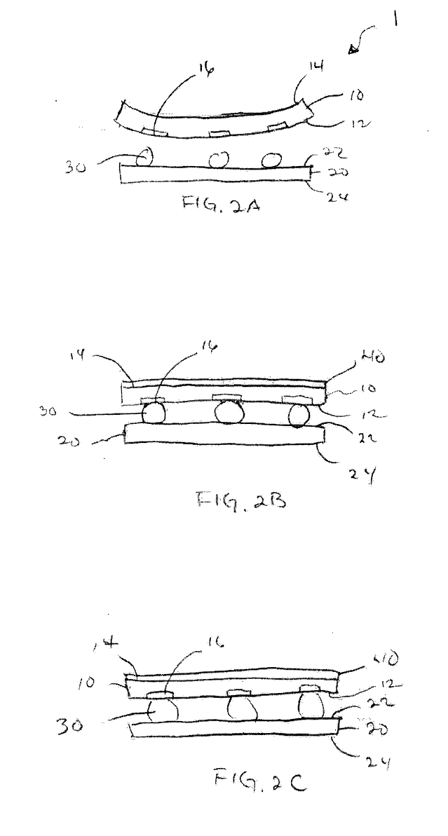

To reduce or eliminate this warpage, the invention provides a compensating structure that counteracts the forces imparted on the device from the shrinkage of the substrate. This may be done, for example by providing an additional layer attached to the rear device surface having a stiffness and coefficient of thermal expansion keyed to the substrate so as to compensate for the warpage forces generated by the substrate. For example, FIG. 2 depicts an exemplary microelectronic package of the invention that is similar to the package depicted in FIG. 1. Like the package depicted in FIG. 1, the package of FIG. 2 also includes a microelectronic device 10 in the form of a semiconductor chip having first and second opposing, parallel, rectangular, major surfaces indicated at 12 and 14, respectively. However, the device 10 also includes a warpage-compensating layer 40 deposited on its rear surface 14. Optionally, surfaces 12 and 14 may be nonplanar. For example, as shown in FIG. 2A, the front device surface 12 may exhibit a convex profile while the rear device surface 14 may exhibit a concave profile.

Like the device of FIG. 1, the device 10 of FIG. 2 may be packaged with a substrate 20 having a higher CTE and substantially planar major first and second major surfaces, indicated at 22, 24. For example, as depicted in FIGS. 2A and 2B, the package comprising the device 10, the substrate 20 and a plurality of interposing solder balls 30 may be heated such that the solder balls 30 are at least partially melted so as to bond the device to the substrate. Notably, as depicted in FIG. 2B, bonding of device 10 and the substrate 20 may be carried out while front device surface 12 is rendered substantially planar and held in parallel facing relationship to the first substrate surface 22. Then, the package may be cooled so that solder balls 30 solidify. Although cooling of the substrate 20 may produce stresses that tend to warp the device 10, the warpage-compensating layer 40 acts to counteract such stresses. As a result, the cooled package, as shown in FIG. 2C, may remain flat.

Although FIG. 2 depicts a package having a microelectronic device in “face-down” relationship to the substrate, the invention allows the device to be positioned “face up” as well. As described above, a face-down orientation allows for rigid electrical and physical attachment of the device contacts to the first surface of the substrate in a flip-chip configuration. A face-up orientation, on the other hand, facilitates wire or lead bonding. Regardless of the orientation, the invention is not limited to any particular electrical bonding technique relative to the device and substrate orientation. However, the warpage-compensating layer typically does not contact more than one electrical contact if at all, particularly, when the warpage-compensating layer is electrically conductive.

Similarly, although FIG. 2 depicts solder bonding of the substrate and the semiconductor member, the substrate and the semiconductor member may be immobilized relative to each other through other bonding techniques as well. For example, an adhesive may be provided between the semiconductor member and the substrate. Any of a number of adhesives known in the art may be used. In some instances, a curable liquid may be placed between the member and the substrate and subjected to curing conditions to form an adhesive layer therebetween. Additional adhesives, e.g., pressure-sensitive adhesives or solvent-containing (aqueous or nonaqueous) adhesive solutions may be used as well.

The invention may be used in conjunction with any of a number of semiconductor members. For example, the semiconductor members of the invention may include a single crystalline material consisting essentially of a single element, e.g., Si or Ge, or a compound semiconductor, e.g., III-V semiconductors such as GaAs. The presence or absence of dopants is not critical to the invention. Alternatively, the semiconductor member may be comprised of a multicrystalline or amorphous semiconductor material such as those often used in photovoltaic applications.

In addition, the semiconductor member used for any of a number of applications including, for example, micro-electromechanical systems (MEMS), optical devices, and microfluidic devices. Often, the semiconductor member may take the form of a microelectronic device. However, devices of the invention may be constructed to contain or exclude specific feature according to the intended use of the device. For example, when the device is not intended for optical applications, the device may contain no optically sensitive and/or emitting element.

Furthermore, the microelectronic devices of the invention may take any of a number of forms, including, but not limited to, the form of a chip, or a wafer. Microelectronic devices typically have opposing front and rear surfaces, wherein the front surface provides electrical accessibility. However, microelectronic devices of any geometry may benefit from the invention. For example, contacts may in some instances be provided on both front and rear surface of the microelectronic device. In any case, the electrical contacts on the microelectronic device may be arranged in an ordered arrangement, i.e., an array. Exemplary arrays types include rectilinear grids, parallel stripes, spirals, and the like.

In general, the stiffness of semiconductor members depend on a number of factors including, for example, their materials properties, such as their elastic and shear moduli, and geometric considerations. Accordingly, given semiconductor members having the same composition, thicker members tend to be stiffer than thinner members. Thus, the invention is particularly suited for use with semiconductor members having a low thickness because they are more prone to warp under the forces described above. For example, the invention may be used with semiconductor members having a thickness less than about 1000 μm. In particular, semiconductor members having a thickness up to about 150 or 250 μm are typically used. Semiconductor members having a thickness of about 125, 100, and 75 μm exhibit increasingly marked warpage reduction when the invention is employed.

The invention may be used with any of a number of substrates. In some instances, the substrate is suitable for electrical connection with the semiconductor member. Alternatively, the substrate may be electrically insulated from the semiconductor member. As the invention is typically used to package microelectronic devices, the substrate may take any of a number of forms and may include, or consist of, a circuit board, an interposer, a carrier, a holder, or another item used in microelectronic packaging applications. In some instances, the substrate may include or be a microelectronic device.

Substrates of the invention typically have a CTE that differs from that of the semiconductor member by a significant degree. For example, the substrate CTE may be greater than the member CTE. Alternatively, the member CTE may be greater than the substrate CTE. In any case, the invention is particularly useful when the CTE of the member and the substrate differ by at least about 10 ppm/° C. Such a large difference between member and substrate CTE typically indicates that the substrate has a composition that differs from that of the semiconductor member. Greater semiconductor warpage will tend occur with an increasing difference between the member and substrate CTE. Thus, for example, a CTE difference of 20 ppm/° C. will tend to generate greater package and/or member warpage than a CTE difference of 10 ppm/° C. In some instances, the invention may be employed with substrates and members having CTEs that differ by at least about 100 or 200 ppm/° C.

In addition, substrates of the invention may exhibit a high stiffness. As is the case with semiconductor members, the stiffness of the substrates of the invention also depends on factors such as elastic modulus and geometric considerations. Accordingly, thicker substrates will tend to be stiffer than their thinner counterparts.

Often, the substrates of the invention include a dielectric material. Polymeric dielectric materials, in particular, may be used to form substrates of the invention. As recited herein, the terms “polymer,” “polymeric,” and the like are used in their ordinary sense and refer to any of numerous natural and synthetic compounds formed from a plurality of monomeric units. Polymer such as dimers, trimers, and oligomers as well as compounds having extremely high molecular weights such as those formed from one-hundred or more monomeric units. In addition, the term “polymer” includes, for example, homopolymers as well copolymers, linear as well as branch polymers, crosslinked as well as uncrosslinked polymers.

Polymeric materials tend to have a CTE that differs to a substantial degree from the member CTE. However, polymeric materials may be selected for the substrate for their other properties as well. For example, when flexibility is desired, polymeric materials may be used as the dielectric material. In some instances, polymeric films may be substantially inextensible. In particular, polyimide is a high performance polymer that has a number of desirable properties for advanced electronic applications. For example, polyimide films have a high degree of thermal stability, reasonably high strength and modulus, low dissipation factor and good dielectric strength. In addition, polyimides are chemically stable, and withstand harsh chemical environments associated with circuit board processing. Suppliers of polyimide base film include: E.I. DuPont de Nemours & Co., Ube Industries, Ltd., and Kaneka Corporation.

Other polymeric materials that be used to form the substrates of the invention include, but are not limited to, polyesters such as polyethylene terephthalate and polyethylene naphthalate, halogenated polymers such as partially and fully fluorinated polyalkanes and partially and fully chlorinated polyalkanes, polycarbonates, epoxies, and acrylate and methacrylate based polymers.

In some instances, the substrate of the invention may be formed from a combination of polymeric and ceramic materials. For example, fiberglass laminates that optionally contain bismaleimide triazine (BT) may serve as the base film. Other composite materials may be used as well. Such laminates typically include an acrylate-based or methacrylate-based polymeric matrix material.

The substrate may include a single layer or plurality of layers. The thickness of each layer may vary, but are, in general, about 5 μm to about 500 μm. In some instances, each layer may have a thickness on the order of about 20 μm to about 100 μm. When a polyimide film is used, thicknesses of 12.5 μm to 125 μm are commercially available, although 25 μm and 50 μm films are most common.

In addition, the substrate generally has at least one major exterior surface that contains electrically conductive regions. Such regions include one or more electrically conductive material. Typically, the regions are made from one or more metals. For example, a conductive region may be comprised of solid copper or a composite composition containing copper particles. Additional metals suitable for use in the invention include, for example, gold, silver, nickel, tin, chromium, iron, aluminum, zinc, combinations thereof, and alloys of any of the foregoing such as brass, bronze, and steel. In some instances, a surface layer may be provided over a base conductive layer of the electrically conductive regions, wherein the surface and base layers have differing compositions. For example, a highly conductive coating such as gold, gold/nickel, gold/osmium or gold/palladium, may be coated on a less conductive material. In addition or in the alternative, a base layer may be plated with a wear resistant coating such as osmium, chromium or titanium nitride. The substrate may also include vias and other internal features that may or may not be conductive.

As discussed above, the inventive multilayer structure also includes a warpage-compensating layer deposited on and/or otherwise physically associated with the semiconductor member. The warpage-compensating layer has a stiffness and a coefficient of thermal expansion keyed to the substrate in a manner effective to reduce warpage of the semiconductor member. Thus, the materials and geometric requirements of the warpage-compensating layer are also generally dependent on the geometry and materials used in the construction of the substrate.

While the warpage-compensating layer may be used that is substantially identical in composition and construction to the substrate, it is generally preferably to use a warpage-compensating layer that is thinner than the substrate. For example, the warpage-compensating layer may have a thickness that is no more than about half that of the substrate. In some instances, the substrate may be ten or more times thicker than the warpage-compensation layer. Accordingly, the warpage-compensating layer may exhibit certain materials properties that differ from those of the substrate. For example, the substrate CTE and the CTE of the warpage-compensating layer may differ significantly, by at least 5 ppm/° C. or 10 ppm/° C. In some instances, the substrate and warpage-compensating layer CTEs may differ by at least about 50 ppm/° C. or 100 ppm/° C. In addition, warpage-compensating layer may have a modulus of elasticity that is at least 50 GPa or 100 GPa greater than that of the substrate.

For substrates that include one or more polymeric materials, it has been found that certain metals are particularly suited for use in forming the warpage-compensating layer. Suitable metals include, without limitation, copper, aluminum, alloys thereof, and combinations of any of the foregoing. It should be noted, however, that certain metals may only be suited for use under certain conditions. For example, pure aluminum may creep over time at about 300° C. but aluminum alloys having about 2% copper may not. In addition, it should also be noted that processes involving vapor deposition, e.g., evaporation, sputtering, physical vapor deposition, etc., as well as other deposition processes, e.g., electroplating, etc., are particularly suited for forming thin metallic warpage-compensating layers.

Depending on a variety of factors, the effectiveness of the warpage-compensating layer may vary. Typically, warpage of the semiconductor member is reduced by at least 10%. In some instances, the stiffness and the coefficient of thermal expansion of the warpage-compensating layer may be effective to reduce warpage of the semiconductor member by at least 20% or 50%. In addition, the warpage-compensating member may be formed in a manner effective to reduce warpage of the semiconductor member according to the conditions to which the inventive structure is expected to experience. Thus, for example, the warpage-compensating layer may be formed to effect package warpage reduction over a selected temperature range. For microelectronic packaging applications, the selected temperature range typically spans at least 60° C. and may in some instances, span at least 100° C. As discussed below, testing has been performed on the inventive structure over a temperature range that encompasses −40° C. to about at least 25° C.

The invention also provides a method for forming a multilayer structure. The method involves depositing a warpage-compensating layer on a major surface of a semiconductor member, and bonding a substrate to another major surface of the semiconductor to form a multilayer structure. Typically, bonding takes place at an elevated temperature, e.g., at least 100° C.

The method may also include any steps and variations thereof necessary to form the inventive multilayer structure. For example, the method may use a semiconductor member, a substrate, and a warpage-compensating layer of different compositions. In addition, the invention may be used to form a warpage-compensating layer having a stiffness and a coefficient of thermal expansion keyed to the substrate in a manner effective to reduce warpage of the semiconductor member and/or the structure over a selected temperature range.

The method is well suited for wafer-scale processing. For example, the warpage-compensating layer may be deposited while the semiconductor member is an integral section of a semiconductor wafer, which may be later sectionalized. Sectionalization may take place before or after the substrate and the semiconductor member are bonded. When plurality of semiconductor members is bonded to a single substrate or when plurality of substrates is bonded to a single member, pick-and-place technologies may be used.

Variations of the present invention will be apparent to those of ordinary skill in the art. For example, while the devices and substrates of the invention may have a rectangular footprint, devices and substrates that have a nonrectangular footprint may be advantageously used as well. In addition, as alluded to above, solders, conductive pastes, and other electrical connection technologies known in the art may be employed to effect electrical communication between any items of the invention. Similarly, solder masks may be used for selectively protecting sections of the member or substrate surface from contact with any solder material. Furthermore, the invention is compatible with encapsulant or molding technologies known in the art. Additional variations of the invention may be discovered upon routine experimentation without departing from the spirit of the present invention.

It is to be understood that while the invention has been described in conjunction with the preferred specific embodiments thereof, the foregoing description and the examples which follow are intended to illustrate and not limit the scope of the invention. Other aspects, advantages and modifications within the scope of the invention will be apparent to those skilled in the art to which the invention pertains.

### EXAMPLE 1

Three sets of experimental microelectronic packages were produced to determine whether package and die warpage as a result of thermal bonding to a polymeric substrate may be reduced by using a warpage-compensating layer. Each set of packages included a p-type silicon die having a thickness of approximately 75 μm. The dies exhibited substantially identical composition and geometry. Each die was a flat semiconductor member having substantially parallel and opposing first and second surfaces. The first and second sets were used as experimental controls and included bare dies, i.e., dies without a warpage-compensating layer. The third set included dies that each have an alloy deposited on the first surface thereof that serves as a warpage-compensating layer. The alloy's composition included about 96% aluminum and 4% copper. The warpage-compensating layer had a thickness of about 5 μm.

Each package was formed by bonding the second surface of its die to a substrate. Each substrate was formed from a commercially available single-sided copper-clad polyimide film. The base polyimide film had a thickness of about 50 μm. The copper was attached to the polyimide film using an adhesive. In addition, solder mask material was also used. Bonding for each die was carried out using the same polymeric die-attach material at the same conditions under a first temperature. Once the packages were cooled to a second temperature, warpage of each package was measured.

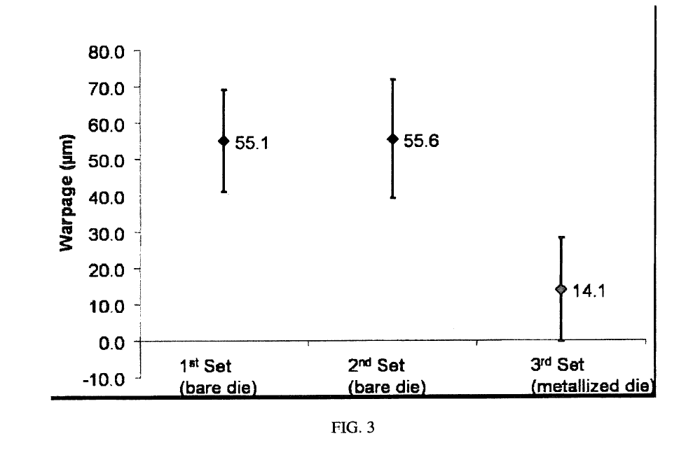

FIG. 3 is a graph that plots the results of the measurements. The measurements show that the first and second sets of packages exhibited a similar degree of package warping, thereby indicating that the test vehicle is reliable. The measurements also show that the packages having a warpage-compensating layer warped to a lesser degree than packages that used bare dies.

### EXAMPLE 2

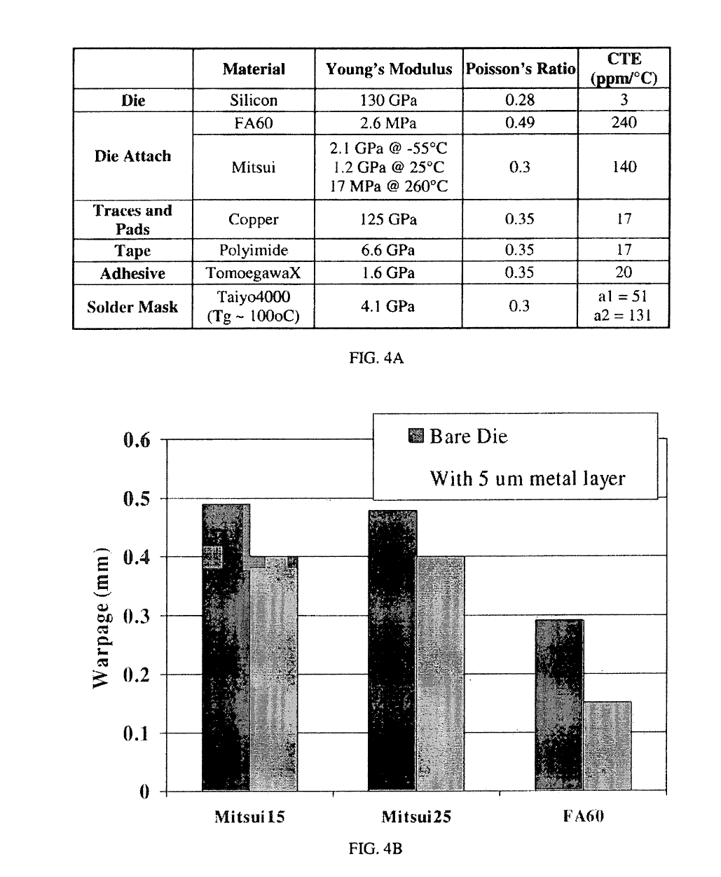

Computer simulations were run to model packages similar to those described in Example 1. Variables in the simulation included different die-attach materials, and the presence or absence of a 5 μm warpage-compensating layer as described above. The simulations were run to simulate package warpage at −40° C. under the assumption that the stress-free temperature for the packages was 150° C. Other factors used for the simulation are set forth in the table of FIG. 4A.

FIG. 4B shows the results of the simulations. Regardless of the die-attach material simulated, significant reduction in package warpage was found when a warpage-compensation layer was present. As a result, the simulations show that the warpage-compensating layer may be effective to reduce die and/or package warpage by about 20-50%.

As these and other variations and combinations of the features discussed above can be utilized without departing from the invention as defined by the claims, the foregoing description of the preferred embodiments should be taken by way of illustration rather than by way of limitation of the invention as defined by the claims.

1. A multilayer structure, comprising:
a semiconductor member having opposing first and second major surfaces;
a warpage-compensating layer deposited on the first major surface and having a composition different from the member; and
a substrate bonded to the second major surface and having a composition different from the warpage-compensating layer,
wherein the warpage-compensating layer has a stiffness and a coefficient of thermal expansion keyed to the substrate in a manner effective to reduce warpage of the semiconductor member by at least 10% over a selected temperature range.

2. The structure of claim 1, wherein the member and the substrate have coefficients of thermal expansion that differ by at least 10 ppm/° C.

3. The structure of claim 2, wherein the coefficients of thermal expansion for the member and the substrate differ by at least 20 ppm/° C.

4. The structure of claim 1, wherein the substrate and the warpage-compensating layer have coefficients of thermal expansion that differ by at least 5 ppm/° C.

5. The structure of claim 4, wherein the coefficients of thermal expansion for the substrate and the warpage-compensating layer differ by at least 10 ppm/° C.

6. The structure of claim 1, wherein warpage-compensating layer has a modulus of elasticity that is at least 50 GPa greater than that of the substrate.

7. The structure of claim 6, wherein the modulus of elasticity for the warpage-compensating layer is at least 100 GPa greater than that of the substrate.

8. The structure of claim 1, wherein the selected temperature range spans at least 60° C.

9. The structure of claim 8, wherein the selected temperature range spans at least 100° C.

10. The structure of claim 9, wherein the selected temperature range encompasses at least −40° C. to about 150° C.

11. The structure of claim 1, wherein the stiffness and the coefficient of thermal expansion of the warpage-compensating layer is effective to reduce warpage of the semiconductor member by at least 20%.

12. The structure of claim 11, wherein the stiffness and coefficient of thermal expansion of the warpage-compensating layer is effective to reduce warpage of the semiconductor member by at least 50%.

13. The structure of claim 1, wherein the semiconductor member has a thickness of no more than about 150 μm.

14. The structure of claim 13, wherein the semiconductor member thickness is no more than about 75 μm.

15. The structure of claim 1, wherein the semiconductor member is a microelectronic device.

16. A microelectronic package, comprising:
a microelectronic device having opposing first and second major surfaces;
a polymeric substrate bonded to the first major surface; and
a metallic warpage-compensating layer deposited on the second major surface and having a stiffness and a coefficient of thermal expansion keyed to the substrate in a manner effective to reduce warpage of the microelectronic device member over a selected temperature range.

17. A method for forming a multilayer structure, comprising:
(a) depositing a warpage-compensating layer on a first major surface of a semiconductor member; and
(b) bonding a substrate to the semiconductor member at a second major surface that opposes the first major surface to form the multilayer structure,
wherein the semiconductor member, the substrate, and the warpage-compensating layer have different compositions, and the warpage-compensating layer has a stiffness and a coefficient of thermal expansion keyed to the substrate in a manner effective to reduce warpage of the semiconductor member over a selected temperature range.

18. The method of claim 17, wherein step (a) is carried out while the semiconductor member is an integral section of a semiconductor wafer.

19. The method of claim 18, further comprising, after step (a) and before step (b), severing the semiconductor member from the semiconductor wafer.

20. The method of claim 17, wherein step (b) is carried out at a temperature of at least 100° C.
